(19) United States
(12) Patent Application Publication
(10) Pub. No.: US 2023/0148229 A1
(43) Pub. Date: May 11, 2023

(54) POWER UNIT

(71) Applicant: Atlas Copco (Wuxi) Compressor Co., Ltd., Wuxi, Jiangsu (CN)

(72) Inventors: Wenjie XI, Wuxi, Jiangsu (CN); Jiawei XU, Wuxi, Jiangsu (CN)

(73) Assignee: Atlas Copco (Wuxi) Compressor Co., Ltd., Wuxi, Jiangsu (CN)

(21) Appl. No.: 17/914,532

(22) PCT Filed: Apr. 1, 2021
(86) PCT No.: PCT/CN2021/084897

§ 371 Date: Sep. 26, 2022

(30) Foreign Application Priority Data
Apr. 1, 2020 (CN) 202010251552.5
Feb. 9, 2021 (CN) 202120366611.3

(51) Int. Cl. H02M 7/00; H05K 7/02; H02G 5/02

(52) U.S. Cl. CPC H02M 7/003; H05K 7/02; H02G 5/025

(57) ABSTRACT

The power unit includes: a substrate having a first side surface at a first side thereof; a tablet structure located at the first side of the substrate; and a power structure configured to be pressed against the first side surface by the tablet structure. The power unit uses the tablet structure to press the power structure against the first side surface of the substrate, thereby achieving a firm and reliable installation of the power structure on the substrate.

### CROSS-REFERENCE TO RELATED APPLICATIONS

The present application claims priority to Chinese Patent Application No. 202010251552.5, titled “POWER UNIT”, filed by ATLAS COPCO (WUXI) COMPRESSOR CO., LTD., on Apr. 1, 2020, and Chinese Patent Application No. 202120366611.3, titled “Heat Sink”, filed by ATLAS COPCO (WUXI) COMPRESSOR CO., LTD., on Feb. 9, 2021, both of which are hereby incorporated by reference in their entireties.

### FIELD OF THE INVENTION

The present disclosure relates to the technical field of inverters and, more particularly, to a power unit.

### BACKGROUND OF THE INVENTION

In an existing inverter, a power structure needs to be mounted on a substrate and is adapted to be connected to a driving circuit board and multiple layers of busbars. However, mounting of the power structure on the substrate is not firm, and it is easy for the power structure to fall from the substrate. Thus, a fixing structure is added in some solutions, to fix the power structure on the substrate. However, in the related art, after the power structure is connected to the driving circuit board and the multiple layers of the busbars through the fixing structure, relatively long pins are required to pass through the busbars and the driving circuit board, resulting in a relatively large volume of an entire device. In addition, pins of respective power structures are likely to interfere with each other, so failures may easily occur. Moreover, when the fixing structure is used to mount the power structure on the substrate in an existing product, a process is complicated, and an installation efficiency is low.

### SUMMARY OF THE INVENTION

The present disclosure aims to solve one of the above technical problems in the related art at least to a certain extent. In view of this, the present disclosure provides a power unit, which is beneficial to improve firmness of installation of the power structure on the substrate.

A power unit according to an embodiment of the present disclosure includes: a substrate having a first side surface at a first side thereof; a tablet structure located at the first side of the substrate; and a power structure configured to be pressed against the first side surface by the tablet structure.

The power unit according to the present disclosure uses the tablet structure to press the power structure against the first side surface of the substrate, thereby achieving a firm and reliable installation of the power structure on the substrate.

According to some embodiments of the present disclosure, the power unit further includes a first holding structure penetrating the tablet structure, in such a manner that the tablet structure is held at the first side of the substrate.

Furthermore, the power unit further includes a second holding structure, the second holding structure being fitted to and connected to the first holding structure, in such a manner that the tablet structure is held at the first side of the substrate.

Alternatively, the first holding structure is configured as a columnar structure, and the second holding structure is configured as a ring structure, with which the columnar structure is sleeved.

Specifically, the first holding structure is perpendicular to the first side surface and has a free end facing away from the substrate, and the first holding structure is sleeved with the second holding structure in a rotatable manner from a side of the tablet structure facing away from the substrate.

According to some embodiments of the present disclosure, the first holding structure is configured as a screw rod having external threads, and the second holding structure is configured as a nut having internal threads.

According to some embodiments of the present disclosure, the second holding structure is pressed against a side of the tablet structure facing away from the substrate.

According to some embodiments of the present disclosure, the tablet structure includes a tablet body formed as a recessed groove structure recessed towards the first side surface, and an opening of the tablet body faces away from the first side surface.

Furthermore, at least a part of the second holding structure is located in the recessed groove of the tablet body, and an end surface of the free end of the first holding structure facing away from the substrate is located in the recessed groove.

Specifically, the second holding structure is pressed against a tablet body bottom wall of the tablet body, the first holding structure penetrates the tablet body bottom wall, and the tablet body bottom wall is provided with a tablet body positioning hole fitted to the first holding structure.

According to some embodiments of the present disclosure, the tablet structure includes a tablet body and a tablet arm connected to the tablet body and configured to press the power structure.

Specifically, the power structure includes a first power structure and a second power structure that are spaced apart from each other. The tablet arm includes a first tablet arm and a second tablet arm. The first tablet arm is configured to press the first power structure, the second tablet arm is configured to press the second power structure, and the tablet body is located between the first power structure and the second power structure.

Further, the first power structure includes a first connecting leg, the second power structure includes a second connecting leg, the first connecting leg and the second connecting leg are respectively located at opposite outer sides of the first power structure and the second power structure, and the tablet body is located between opposite inner sides of the first power structure and the second power structure.

Alternatively, an angle between a direction along which the first connecting leg protrudes from the first power structure and a direction along which the second connecting leg protrudes from the second power structure is approximately 180 degrees.

According to some embodiments of the present disclosure, the first power structure and the second power structure face towards each other in a first direction of the substrate, there is a plurality of the first power structures arranged on the substrate in a second direction of the substrate, there is a plurality of the second power structures arranged on the substrate along the second direction, and there is a plurality of the tablet structures arranged along the second direction. The first direction and the second direction are perpendicular to each other.

Further, the plurality of the first power structures, the plurality of the tablet structures, and the plurality of the second power structures are in one-to-one correspondence in the first direction.

According to some embodiments of the present disclosure, the plurality of the tablet structures is connected into one piece by a tablet connecting portion.

Further, the tablet connecting portion is connected between tablet bodies of two adjacent tablet structures.

According to some embodiments of the present disclosure, the tablet structure includes a tablet body and a tablet arm. The first holding structure penetrates the tablet body, and the tablet arm is connected side by side to the tablet body in the first direction of the substrate and configured to press the power structure. There is a plurality of the tablet structures connected to each other in the second direction of the substrate, and the first direction and the second direction are perpendicular to each other.

Further, the tablet arms include a first tablet arm and a second tablet arm that are symmetrically connected to two sides of the tablet body. Moreover, tablet bodies of two adjacent tablet structures are connected to each other through a tablet connecting portion.

Specifically, the tablet body is formed as a recessed groove structure recessed towards the first side surface, an opening of the tablet body faces away from the first side surface, the first tablet arm and the second tablet arm are respectively connected to two ends of the opening of the tablet body, and the first tablet arm and the second tablet arm extend in directions facing away from each other.

According to some embodiments of the present disclosure, the power unit further includes: a positioning portion for positioning the power structure on the substrate.

According to some embodiments of the present disclosure, the positioning portion includes a positioning sheet, a through positioning opening is provided on the positioning sheet, and the positioning opening matches the power structure.

Alternatively, the positioning sheet is further provided with an annular positioning rib surrounding the positioning opening and matching an outer peripheral surface of the power structure.

According to some embodiments of the present disclosure, the positioning sheet is an insulating positioning sheet and adhesively fixed to the first side surface of the substrate.

According to some embodiments of the present disclosure, the positioning sheet is provided with a positioning sheet through hole for matching the first holding structure and allowing the first holding structure to pass through to form positioning fitting.

According to some embodiments of the present disclosure, the positioning portion includes a recess formed on the first side surface of the substrate, and the recess matches the outer peripheral surface of the power structure.

According to some embodiments of the present disclosure, the power unit further includes a heat-insulation structure arranged on the first side surface of the substrate in a form of surrounding the power structure.

According to some embodiments of the present disclosure, the first side surface of the substrate is a side surface facing towards the busbar.

According to some embodiments of the present disclosure, the tablet structure is configured as a seagull wing shape and includes a tablet body, a first tablet arm and a second tablet arm. The first tablet arm and the second tablet arm are symmetrically connected to two sides of the tablet body, and free ends of the first tablet arm and the second tablet arm each have a bending section bending towards the substrate.

The additional aspects and advantages of the present disclosure will be partly given in the following description, and some will become obvious from the following description or be learned through practice of the present disclosure.

### BRIEF DESCRIPTION OF DRAWINGS

FIG. 1 is a perspective assembled schematic view of a power unit;

FIG. 2 is an assembled side view of a power unit;

FIG. 3 is a perspective exploded schematic view of a power unit;

FIG. 4 is an exploded side view of a power unit;

FIG. 5 is a perspective assembled schematic view of a power unit when a ridge is provided on a substrate;

FIG. 6 is a perspective exploded schematic view of a power unit when a recess is provided on a substrate;

FIG. 7 is a perspective assembled schematic view of a power unit when a recess is provided on the substrate;

FIG. 8 is an assembled side view of a power unit when a recess is provided on a substrate; and

FIG. 9 is a perspective schematic view of a tablet structure.

### REFERENCE SIGNS

power unit 100, substrate 10, ridge 11, recess 12, tablet structure 20, tablet body 21, tablet body positioning hole 211, tablet arm 22, first tablet arm 221, second tablet arm 222, tablet connecting portion 23, bending section 24, power structure 30, first power structure 31, first connecting leg 311, second power structure 32, second connecting leg 321, first pin 331, second pin 332, third pin 333, holding structure 45, first holding structure 40, second holding structure 50, positioning sheet 60, positioning opening 61, annular positioning rib 62, positioning sheet through hole 63, and heat-insulation structure 60′.

### DETAILED DESCRIPTION OF THE INVENTION

The embodiments of the present disclosure will be described in detail below, examples of the embodiments are shown in the accompanying drawings, and same or similar reference numerals indicate same or similar elements or elements having same or similar functions all the way. The embodiments described below with reference to the accompanying drawings are exemplary, and intended to explain the present disclosure, but should not be understood as a limitation to the present disclosure.

In the description of the present disclosure, it should be understood that orientations or positional relationships indicated by the terms “longitudinal”, “lateral”, “length”, “width”, “thickness”, “upper”, “lower”, “front”, “rear”, “left”, “right”, “vertical”, “horizontal”, “top”, “bottom”, “inner”, “outer” and the like are based on orientations or positional relationships shown in the drawings and are only for the convenience of describing the present disclosure and simplifying the description, rather than indicating or implying that the referred device or element must have a specific orientation and be constructed and operated in a specific orientation, and therefore it cannot be understood as a limitation of the present disclosure.

In the present disclosure, unless otherwise clearly stipulated and limited, terms such as terms “installation”, “in communication with”, “connected”, “fixed” should be understood in a broad sense, for example, it can be fixed connection, detachable connection, or integrated into one piece; it can be a mechanical connection, an electrical connection, or it can be communication with each other; it can be direct connection or indirect connection through an intermediate medium, and it can be communication of interiors of two components or an interaction relationship between two components. For those of ordinary skill in the art, the specific meaning of the above terms in the present disclosure can be understood according to specific circumstances.

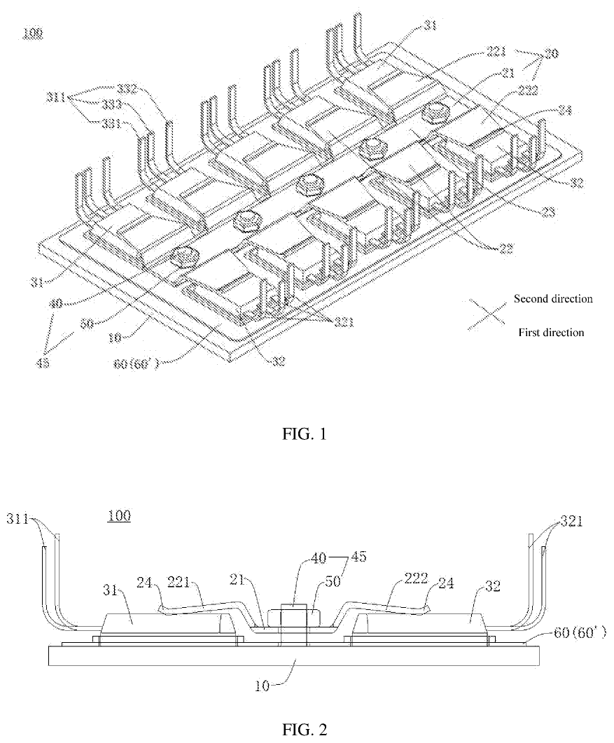

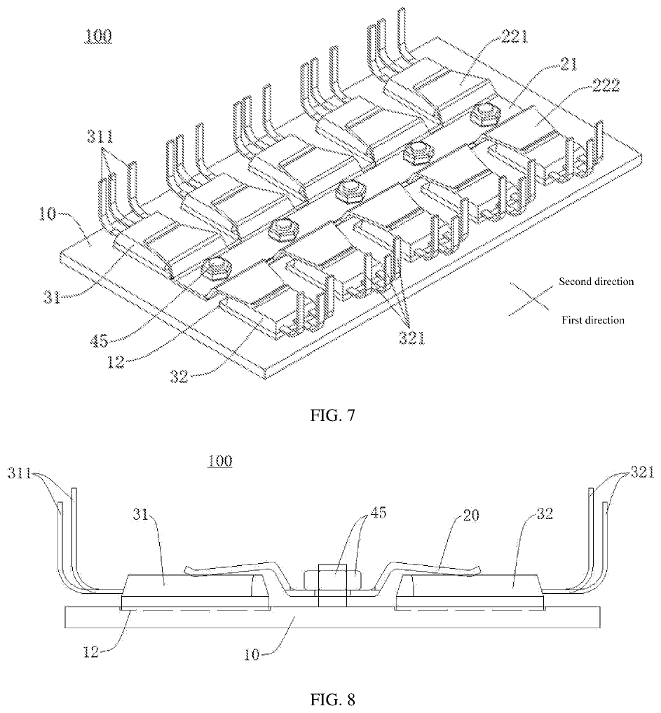

A power unit 100 according to an embodiment of the present disclosure will be described in detail below with reference to FIGS. 1 to 9.

Referring to FIGS. 1-8, the power unit 100 according to the embodiment of the present disclosure may include: a substrate 10, a tablet structure 20 and a power structure 30. The substrate 10 has a first side surface a first side (i.e. an upper side in FIG. 2) thereof. The tablet structure 20 is located on the first side of the substrate 10. The power structure 30 is pressed against the first side surface of the substrate 10 by the tablet structure 20.

The power unit 100 according to the embodiment of the present disclosure uses the tablet structure 20 to press the power structure 30 against the first side surface of the substrate 10, thereby firmly and reliably mounting of the power structure 30 on the substrate 10.

Referring to FIGS. 1 to 9, the power unit 100 further includes a holding structure 45. The holding structure 45 includes a first holding structure 40. The first holding structure 40 extends from the substrate 10 in a direction facing away from the first side surface, and penetrates the tablet structure 20, in such a manner that the tablet structure 20 is held at the first side of the substrate 10 and thus the power structure 30 is held at the first side of the substrate 10 by the tablet structure 20 pressing the power structure 30. In other words, referring to FIGS. 2 and 8, the first holding structure 40 penetrates the tablet structure 20 from bottom to top, and the tablet structure 20 is held at the first side of the substrate 10 by the first holding structure 40. That is, when the first holding structure 40 penetrates the tablet structure 20, a relative position between the tablet structure 20 and the substrate 10 is determined, and the first holding structure 40 can play a role in positioning the tablet structure 20.

In some unshown embodiments, the first holding structure 40 extends towards the substrate 10 and penetrates the tablet structure 20 from top to bottom, in such a manner that the tablet structure 20 is fixed at the first side of the substrate 10. The first holding structure 40 may be a bolt or a similar connecting structure.

In some other unshown embodiments, the tablet structure 20 can also be directly fixed, such as welded, on the substrate 10, while the holding structure 45 is eliminated, thereby facilitating reducing the number of connecting components and thus reducing a weight of the power unit 100.

Further, referring to FIGS. 1 to 8, the holding structure 45 further includes a second holding structure 50. The second holding structure 50, through being fitted and connected to the first holding structure 40, makes the tablet structure 20 be held at the first side of the substrate 10. The second holding structure 50 is connected to the first holding structure 40 at a side of the tablet structure 20 facing away from the substrate 10. As shown in FIG. 2, the second holding structure 50 is connected to the first holding structure 40 at an upper side of the tablet structure 20, and there is a wide space at an upper side of the tablet structure 20, leaving an operation space for installation and disassembly of the second holding structure 50. The tablet structure 20 is sandwiched between the second holding structure 50 and the substrate 10, and the power structure 30 is sandwiched between the tablet structure 20 and the substrate 10.

In the description of the present disclosure, terms “first” and “second” are only used for descriptive purposes and cannot be understood as indicating or implying relative importance or implicitly indicating the number of technical features indicated. Thus, the features defined with the “first” and “second” may explicitly or implicitly include one or more of these features. In addition, unless otherwise specifically defined, “plurality” means at least two, such as two, three, etc.

In the embodiment shown in FIGS. 1 to 8, the first holding structure 40 is configured as a columnar structure, the second holding structure 50 is configured as a ring structure, with which the columnar structure is sleeved, and the tablet structure 20 is sandwiched between the second holding structure 50 and the substrate 10, to prevent the tablet structure 20 from being separated from the substrate 10.

Specifically, the first holding structure 40 is perpendicular to the first side surface of the substrate 10, and the first holding structure 40 has a free end far away from the substrate 10, and the first holding structure 40 is sleeved with the second holding structure 50 in a rotatable manner from the side of the tablet structure 20 facing away from the substrate 10, thereby facilitating a quick connection or detachment between the second holding structure 50 and the first holding structure 40.

In some alternative embodiments, the first holding structure 40 is configured as a screw rod having external threads, the second holding structure 50 is configured as a nut having internal threads, and the nut is fitted to the screw rod by screwing, to facilitate installation and disassembly of the tablet structure 20.

Referring to FIGS. 1 to 8, the second holding structure 50 is pressed against the side of the tablet structure 20 facing away from the substrate 10, and the second holding structure 50 can exert on the tablet structure 20 a pressing force towards the substrate 10, to prevent the tablet structure 20 from shaking, thereby leading to the more reliable connection between the tablet structure 20 and the substrate 10.

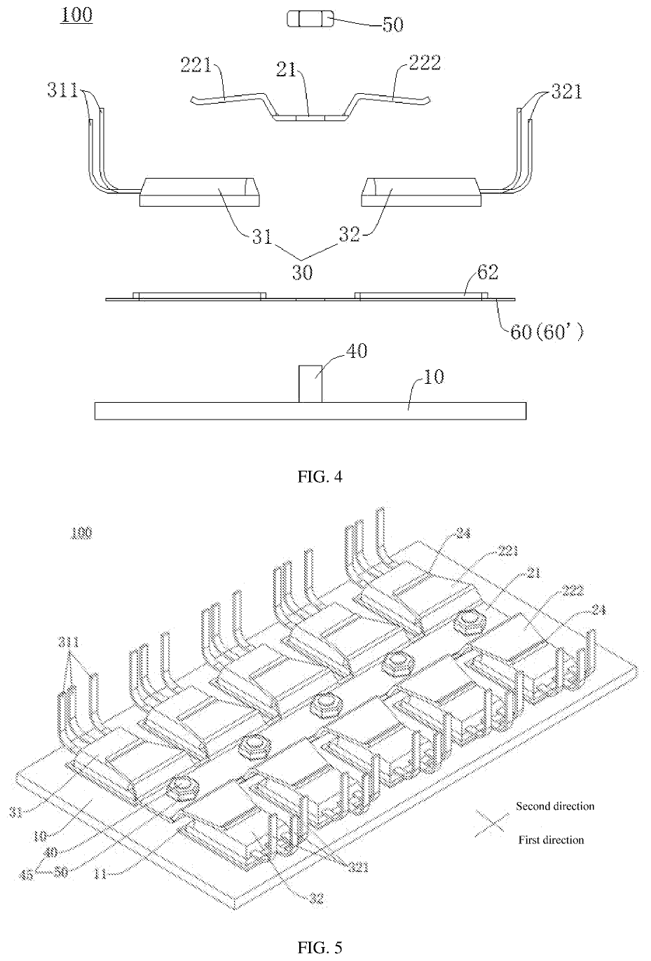

Referring to FIGS. 1 to 9, the tablet structure 20 includes a tablet body 21 formed as a recessed groove structure recessed towards the first side surface. An opening of the tablet body 21 faces away from the first side surface. Referring to FIGS. 2 and 4, the tablet body 21 is formed as a recessed groove structure that is recessed downward, and the opening of the tablet body 21 faces upward.

Further, at least a part of the second holding structure 50 is located in the recessed groove of the tablet body 21, and an end surface of the free end of the first holding structure 40 facing away from the substrate 10 (that is, an upper end surface of the first holding structure 40) is also located in the recessed groove, such that a distance between the end surface of the free end of the first holding structure 40 facing away from the substrate 10 and the substrate 10 can be shortened, and a distance between the second holding structure 50 and the substrate 10 can be shortened. Thus, the holding structure 45 is located in the recessed groove of the tablet body 21 as much as possible, which can reduce a dimension of the power unit 100 in a height direction and form a relatively large usable space above the tablet structure 20, thereby facilitating leaving an installation space for other components and thus preventing mutual interference during the installation.

In an embodiment shown in FIG. 2, an entirety of the second holding structure 50 is located in the recessed groove, and the upper end surface of the first holding structure 40 is also located in the recessed groove, so that the dimension of the power unit 100 in the height direction can be further reduced.

Referring to FIG. 2, an overlapping dimension of the second holding structure 50 and the power structure 30 in a thickness direction of the power structure 30 exceeds half of a thickness of the second holding structure 50, such that the second holding structure 50 can be located in the recessed groove of the tablet body 21 as much as possible, thereby further reducing the distance between the second holding structure 50 and the substrate 10.

Referring to FIGS. 1 to 3, 5 and 7 to 9, the second holding structure 50 is pressed against a tablet body bottom wall of the tablet body 21, the first holding structure 40 penetrates the tablet body bottom wall, and a tablet body positioning hole 211 fitted to the first holding structure 40 is formed in the tablet body bottom wall, so that after the first holding structure 40 penetrates the tablet body positioning hole 211 on the tablet body bottom wall, the tablet structure 20 can be preliminarily positioned, to facilitate subsequently using the second holding structure 50 to fix the tablet structure 20.

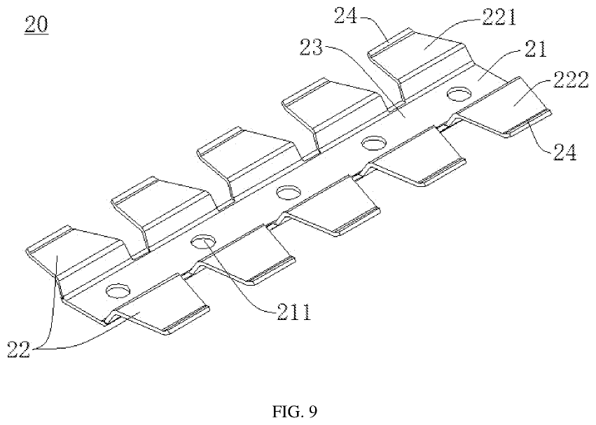

Referring to FIG. 9, the tablet structure 20 includes a tablet body 21 and a tablet arm 22. The tablet arm 22 is connected to the tablet body 21. Referring to FIGS. 1 to 2 and 5, the tablet arm 22 is used to press the power structure 30, and the power structure 30 is sandwiched between the tablet structure 20 and the substrate 10.

Referring to FIGS. 1 to 8, the power structure 30 may include a first power structure 31 and a second power structure 32 that are spaced apart from each other. The tablet arm 22 includes a first tablet arm 221 and a second tablet arm 222. The first tablet arm 221 is used to press the first power structure 31, the second tablet arm 222 is used to press the second power structure 32, the tablet body 21 is located between the first power structure 31 and the second power structure 32, and the holding structure 45 is also located between the first power structure 31 and the second power structure 32.

Further, the first power structure 31 includes a first connecting leg 311, the second power structure 32 includes a second connecting leg 321, the first connecting leg 311 and the second connecting leg 321 are respectively located on opposite outer sides of the first power structure 31 and the second power structure 32, and the tablet body 21 is located between opposite inner sides of the first power structure 31 and the second power structure 32.

Alternatively, an angle between a direction along which the first connecting leg 311 protrudes from the first power structure 31 and a direction along which the second connecting leg 321 protrudes from the second power structure 32 is approximately 180 degrees. That is, pins of the first connecting leg 311 and the second connecting leg 321 are both provided outwards, leaving a middle space between the first power structure 31 and the second power structure 32, which allows the holding structure 45 to fix the tablet structure 20 on the substrate 10 from the middle space.

The pins of the first connecting leg 311 and the second connecting leg 321 each include: a first pin 331, a second pin 332 and a third pin 333. Each of the pins is adapted to be electrically connected to the driving circuit board or a corresponding busbar.

Referring to FIGS. 2 and 4, the first connecting leg 311 protrudes from the first power structure 31 towards left, and the second connecting leg 321 protrudes from the second power structure 32 towards right, and an angle between the two directions is approximately 180 degrees, such that it is possible to prevent an interference between the first power structure 31 and the second power structure 32 due to a relatively close distance between the first connecting leg 311 and the second connecting leg 321 when the first connecting leg 311 and the second connecting leg 321 face towards each other. Moreover, when the first power structure 31 and the second power structure 32 are connected to the corresponding busbar or driving circuit board, the first connecting leg 311 and the second connecting leg 321 both face outward, and there is plenty of space to facilitate corresponding operations.

Referring to FIGS. 1, 3 and 5 to 7, the first power structure 31 and the second power structure 32 are spaced apart in a first direction of the substrate 10, for example, facing towards each other. There is a plurality of the first power structures 31 arranged on the substrate 10 in a second direction of the substrate 10, a plurality of the second power structures 32 arranged on the substrate 10 in the second direction, and a plurality of tablet structures 20 arranged along the second direction. The first direction and the second direction are perpendicular to each other. When the substrate 10 is rectangular, the first direction may be a width direction of the substrate 10 and the second direction may be a length direction of the substrate 10.

Further, the plurality of the first power structures 31, the plurality of the tablet structures 20, and the plurality of the second power structures 32 are in one-to-one correspondence in the first direction. A pair of oppositely arranged first power structure 31 and second power structure 32 can be pressed against the substrate 10 by the same tablet structure 20.

In some embodiments, the plurality of the tablet structures 20 may be mutually independent.

In the embodiments shown in FIGS. 1, 3 and 9, the plurality of the tablet structures 20 is connected into one piece by a tablet connecting portion 23, such that an assembly process of the plurality of the tablet structures 20 is saved, thereby facilitating improving an assembly efficiency of the power unit 100. Moreover, the tablet structures 20 connected into one piece can press a plurality of the power structures 30 concurrently, leading to a high crimping efficiency. The one-piece tablet structure 20 is pressed against the substrate 10 by two or more of the holding structures 45.

Further, the tablet connecting portion 23 is connected between the tablet bodies 21 of two adjacent tablet structures 20, and a width of the tablet connecting portion 23 may be equal to a width of the tablet body 21.

In the embodiment shown in FIGS. 1, 3 and 9, the tablet structure 20 includes a tablet body 21 and a tablet arm 22. The first holding structure 40 penetrates the tablet body 21, the tablet arm 22 is connected side by side with the tablet body 21 in the first direction of the substrate 10, and the tablet arm 22 is used to press the power structure 30. There is a plurality of the tablet structures 20 connected to each other in the second direction of the substrate 10, and the first direction and the second direction are perpendicular to each other.

Further, the tablet arm 22 may include: a first tablet arm 221 and a second tablet arm 222 that are symmetrically connected to both sides of the tablet body 21. In addition, the tablet bodies 21 of two adjacent ones of the tablet structures 20 are connected to each other through the tablet connecting portion 23.

Referring to FIGS. 2, 4, and 9, the tablet body 21 is formed as a recessed groove structure recessed towards the first side surface, the opening of the tablet body 21 faces away from the first side surface, the first tablet arm 221 and the second tablet arm 222 are respectively connected to two ends of the opening of the tablet body 21, and the first tablet arm 221 and the second tablet arm 222 extend in directions facing away from each other. Referring to FIGS. 2 and 4, the tablet body 21 is formed as a recessed groove structure that is recessed downward, the opening of the tablet body 21 faces upward, the first tablet arm 221 extends to the left, and the second tablet arm 222 extends to the right.

In some alternative embodiments, the power unit 100 may further include: a positioning portion for positioning the power structure 30 on the substrate 10, to ensure that a position of the power structure 30 on the substrate 10 is accurate, to prevent the power structure 30 from shaking randomly on the substrate 10.

In the embodiments shown in FIGS. 1 to 4, the positioning portion includes: a positioning sheet 60. The positioning sheet 60 is provided with a through positioning opening 61 matching the power structure 30. For example, an outer peripheral surface of the power structure 30 and the positioning opening 61 are both rectangular, the power structure 30 is positioned in the positioning opening 61, and a bottom of the power structure 30 is directly attached to the substrate 10. The substrate 10 can be a metal substrate 10, heat of the power structure 30 can be transferred to the substrate 10, and a cooling device or a heating device may be provided under the substrate 10 to cool or heat the power structure 30.

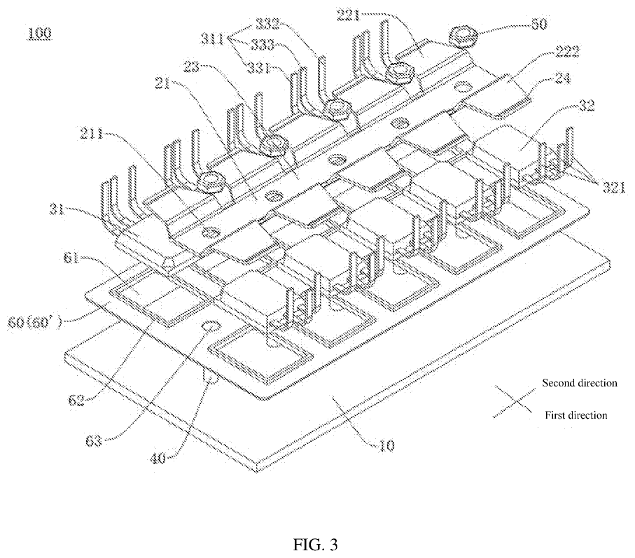

Alternatively, as shown in FIGS. 3-4, the positioning sheet 60 is also provided with an annular positioning rib 62 surrounding the positioning opening 61, and the annular positioning rib 62 matches the outer peripheral surface of the power structure 30. The annular positioning rib 62 protrudes from a surface of the positioning sheet 60, so that positioning firmness of the power structure 30 can be increased, thereby leading to the better positioning effect.

In the embodiments shown in FIGS. 1 to 4, the positioning sheet 60 is an insulating positioning sheet, and the positioning sheet 60 is adhesively fixed to the first side surface of the substrate 10.

Referring to FIGS. 1 and 3, the positioning sheet 60 is provided with a positioning sheet through hole 63 for matching the first holding structure 40 and allowing the first holding structure 40 to pass through to form positioning fitting, and after the first holding structure 40 passes through the positioning sheet through hole 63, the positioning sheet 60 can be initially positioned. The first holding structure 40 passes through the positioning sheet through hole 63 on the positioning sheet 60 and the tablet body positioning hole 211 on the tablet body 21 to be connected to the second holding structure 50, so as to fix the positioning sheet 60 and the tablet structure 20 between the second holding structure 50 and the substrate 10.

In the embodiment shown in FIG. 5, the positioning portion includes a ridge 11 provided on the first side surface of the substrate 10, thereby saving the positioning sheet 60, which facilitates reducing the number of components while saving assembly man-hours.

Alternatively, the ridge 11 is a continuous annular ridge 11, and the annular ridge 11 matches the outer peripheral surface of the power structure 30.

Alternatively, the ridge 11 corresponding to each power structure 30 is divided into four sections, and the four sections are respectively located on four side surfaces of the rectangular power structure 30, thereby limiting the power structure 30 all around, so that the power structure 30 is better positioned on the substrate 10.

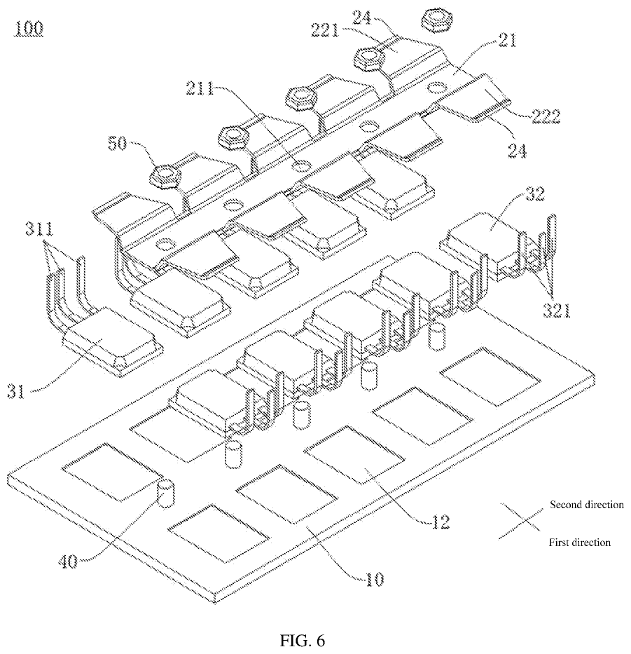

In the embodiment shown in FIGS. 6-8, the positioning portion includes a recess 12 formed on the first side surface of the substrate 10, and a circumferential wall of the recess 12 is adapted to match the outer periphery surface of the power structure 30. Preferably, the recess 12 is a blind recess. As shown in FIG. 8, a bottom wall of the recess 12 is adapted to be attached to a bottom surface of the power structure 30, in order to support the power structure 30. This embodiment also saves the positioning sheet 60, which facilitates reducing the number of the components and saving assembly man-hours. Moreover, the recess 12 is directly provided on the first side surface of the substrate 10, leading to simple process and strong operability. Referring to FIG. 8, the bottom surface of the power structure 30 is lower than the first side surface of the substrate 10, such that a total height of the power structure 30 and the substrate 10 after assembly can be shortened, and a volume of the power unit 100 can be reduced.

In some alternative embodiments, the power unit 100 may further include a heat-insulation structure 60′ provided on the first side surface of the substrate 10 in a form of surrounding the power structure 30. The heat-insulation structure 60′ is located between the power structure 30 and the substrate 10, and the heat-insulation structure 60′ can separate the power structure 30 from the substrate 10, to prevent the heat of the power structure 30 from affecting the components under the substrate 10 while preventing heat under the substrate 10 from being transferred upward to the power structure 30.

In some alternative embodiments, the first side surface of the substrate 10 faces towards the busbar.

Referring to FIGS. 2, 4, and 9, the tablet structure 20 is constructed as a seagull wing shape, and the tablet structure 20 may include a tablet body 21, a first tablet arm 221, and a second tablet arm 222. The first tablet arm 221 and the second tablet arm 222 are symmetrically connected to both sides of the tablet body 21, and free ends of the first tablet arm 221 and the second tablet arm 222 each have a bending section 24 bending towards the substrate 10. The bending section 24 is adapted to press the power structure 30 so that the power structure 30 is pressed against the substrate 10.

A relatively large planar space is formed above the tablet structure 20, leaving an installation space for other components (taking the busbar as an example) while significantly reducing dimensions of the power unit 100 and the busbar assembly in the height direction.

In the description of this specification, the description with reference to terms “an embodiment”, “some embodiments”, “examples”, “specific examples” or “some examples” etc. means that specific features, structures, materials or characteristics described in conjunction with the embodiments or the examples are included in at least one embodiment or example of the present disclosure. In this specification, schematic representations of the above terms do not necessarily refer to the same embodiment or example. Moreover, the described specific features, structures, materials, or characteristics may be combined in any one or more embodiments or examples in a suitable manner. In addition, those skilled in the art can join and combine different embodiments or examples described in this specification.

Although the embodiments of the present disclosure have been shown and described above, it can be understood that the above embodiments are exemplary and cannot be construed as limiting the present disclosure, and those of ordinary skill in the art can make variations, modifications, substitutions, and modifications to the above embodiments within the scope of the present disclosure.

1.-30. (canceled)

31. A power unit, comprising:
a substrate having a first side surface at a first side thereof;
a tablet structure located at the first side of the substrate;
a power structure configured to be pressed against the first side surface by the tablet structure; and
a first holding structure penetrating the tablet structure, in such a manner that the tablet structure is held at the first side of the substrate;
the tablet structure comprises a tablet body and a tablet arm connected to the tablet body and configured to press the power structure.

32. The power unit according to claim 31, further comprising a second holding structure, the second holding structure being fitted to and connected to the first holding structure, in such a manner that the tablet structure is held at the first side of the substrate.

33. The power unit according to claim 32, wherein the first holding structure is configured as a columnar structure, and the second holding structure is configured as a ring structure, with which the columnar structure is sleeved; the first holding structure is perpendicular to the first side surface and has a free end facing away from the substrate, and the first holding structure is sleeved with the second holding structure in a rotatable manner from a side of the tablet structure facing away from the substrate, the first holding structure being configured as a screw rod having an external thread, and the second holding structure being configured as a nut having an internal thread.

34. The power unit according to claim 32, wherein the second holding structure is pressed against a side of the tablet structure facing away from the substrate.

35. The power unit according to claim 32, wherein the tablet body is formed as a recessed groove structure recessed towards the first side surface, and an opening of the tablet body faces away from the first side surface.

36. The power unit according to claim 35, wherein at least a part of the second holding structure is located in the recessed groove of the tablet body, and an end surface of the free end of the first holding structure facing away from the substrate is located in the recessed groove.

37. The power unit according to claim 35, wherein the second holding structure is pressed against a tablet body bottom wall of the tablet body, the first holding structure penetrates the tablet body bottom wall, and the tablet body bottom wall is provided with a tablet body positioning hole fitted to the first holding structure.

38. The power unit according to claim 31, wherein
the power structure comprises a first power structure and a second power structure that are spaced apart from each other;
the tablet arm comprises a first tablet arm and a second tablet arm, the first tablet arm is configured to press the first power structure, the second tablet arm is configured to press the second power structure, and the tablet body is located between the first power structure and the second power structure.

39. The power unit according to claim 38, wherein the first power structure comprises a first connecting leg, the second power structure comprises a second connecting leg, and wherein the first connecting leg and the second connecting leg are respectively located at opposite outer sides of the first power structure and the second power structure, and the tablet body is located between opposite inner sides of the first power structure and the second power structure.

40. The power unit according to claim 39, wherein an angle between a direction along which the first connecting leg protrudes from the first power structure and a direction along which the second connecting leg protrudes from the second power structure is approximately 180 degrees.

41. The power unit according to claim 38, wherein the first power structure and the second power structure face towards each other in a first direction of the substrate, a plurality of the first power structures is arranged on the substrate in a second direction of the substrate, a plurality of the second power structures is arranged on the substrate along the second direction, a plurality of the tablet structures is arranged along the second direction, and the first direction and the second direction are perpendicular to each other.

42. The power unit according to claim 41, wherein the plurality of the tablet structures is connected into one piece by a tablet connecting portion, the tablet connecting portion being connected between tablet bodies of two adjacent tablet structures.

43. The power unit according to claim 31, wherein the tablet structure comprises a tablet body and a tablet arm, the first holding structure penetrates the tablet body, and the tablet arm is connected side by side to the tablet body in the first direction of the substrate and configured to press the power structure; and a plurality of the tablet structures is provided and connected to each other in the second direction of the substrate, and the first direction and the second direction are perpendicular to each other.

44. The power unit according to claim 43, wherein,
the tablet arms comprise a first tablet arm and a second tablet arm that are symmetrically connected to two sides of the tablet body, and
tablet bodies of two adjacent tablet structures are connected to each other through a tablet connecting portion.

45. The power unit according to claim 44, wherein, the tablet body is formed as a recessed groove structure recessed towards the first side surface, an opening of the tablet body faces away from the first side surface, the first tablet arm and the second tablet arm are respectively connected to two ends of the opening of the tablet body, and the first tablet arm and the second tablet arm extend in directions facing away from each other.

46. The power unit according to claim 31, further comprising a positioning portion for positioning the power structure on the substrate.

47. The power unit according to claim 31, further comprising a heat-insulation structure arranged on the first side surface of the substrate in a form of surrounding the power structure.

48. The power unit according to claim 31, wherein the tablet structure is configured as a seagull wing shape and comprises a tablet body, a first tablet arm and a second tablet arm, the first tablet arm and the second tablet arm are symmetrically connected to two sides of the tablet body, and free ends of the first tablet arm and the second tablet arm each have a bending section bending towards the substrate.
